(19) United States
(12) Patent Application Publication
(10) Pub. No.: US 2012/0299603 A1
(43) Pub. Date: Nov. 29, 2012

(54) ON-LINE MONITORING SYSTEM OF INSULATION LOSSES FOR UNDERGROUND POWER CABLES

(75) Inventor: Tiebin Zhao, Charlotte, NC (US)

(73) Assignee: ELECTRIC POWER RESEARCH INSTITUTE, INC., Charlotte, NC (US)

(21) Appl. No.: 13/478,979

(22) Filed: May 23, 2012

Related U.S. Application Data
(60) Provisional application No. 61/489,859, filed on May 25, 2011.

(51) Int. Cl. G01R 31/02

(52) U.S. Cl. 324/551

(57) ABSTRACT

A monitoring system adapted to assess insulation losses of an underground power cable includes a cable circuit having first and second, spaced-apart terminals. The cable circuit is disposed along a section of the underground power cable. The system further includes a communications device adapted to transmit data gathered at the first and second terminals, and a processor adapted to receive and process the data measured at the same time with the synchronization device and transmitted from the communications device.

This application claims the benefit of Provisional Application No. 61/489,859 filed on May 25, 2011.

### BACKGROUND OF THE INVENTION

This application relates to a monitoring system and method for monitoring and continually assessing the condition of underground power cables.

Underground power cables require condition assessment to ensure long-term performance and reliable operations. Conventional practices often involve off-line insulation loss or dissipation factor measurements.

Dissipation factor measurements are routinely performed on different types of power system equipment as a diagnostic test. However capacitance charging currents are usually much higher for laminar dielectric cables, compared with substation equipment. One prior art instrument for measuring insulation dissipation has been used to perform field dissipation factor measurements on numerous transmission cable systems. The equipment considers the high capacitance charging power requirements of most cable circuits. A disadvantage of the system is that the measurements need a circuit outage and are time consuming. The system also needs a standard capacitor connected to the phase conductor—adding such a device permanently to the system for long-term monitoring would be costly and have high maintenance requirements.

### BRIEF SUMMARY OF THE INVENTION

These and other shortcomings of the prior art are addressed by the present invention, which provides a monitoring system and method for providing continuous monitoring and trending of the condition of underground power cables without requiring circuit outages.

According to one aspect of the present invention, a monitoring system adapted to assess insulation losses of an underground power cable includes a cable circuit having first and second, spaced-apart terminals. The cable circuit is disposed along a section of the underground power cable. The system further including a communications device adapted to transmit data gathered at the first and second terminals, and a processor adapted to receive and process the data from the communications device.

According to another aspect of the present invention, a method of determining insulation losses of an underground power cable includes the steps of providing a cable circuit having first and second, spaced-apart terminals, acquiring data signals collected at the first and second terminals, and transmitting the data signals to a processor. The method further includes the steps of using the processor to process the data signals, and displaying results of the processed data signals.

### BRIEF DESCRIPTION OF THE DRAWINGS

The subject matter that is regarded as the invention may be best understood by reference to the following description taken in conjunction with the accompanying drawing figures in which:

FIG. 1 is a schematic of a cable circuit according to an embodiment of the invention.

### DETAILED DESCRIPTION OF THE INVENTION

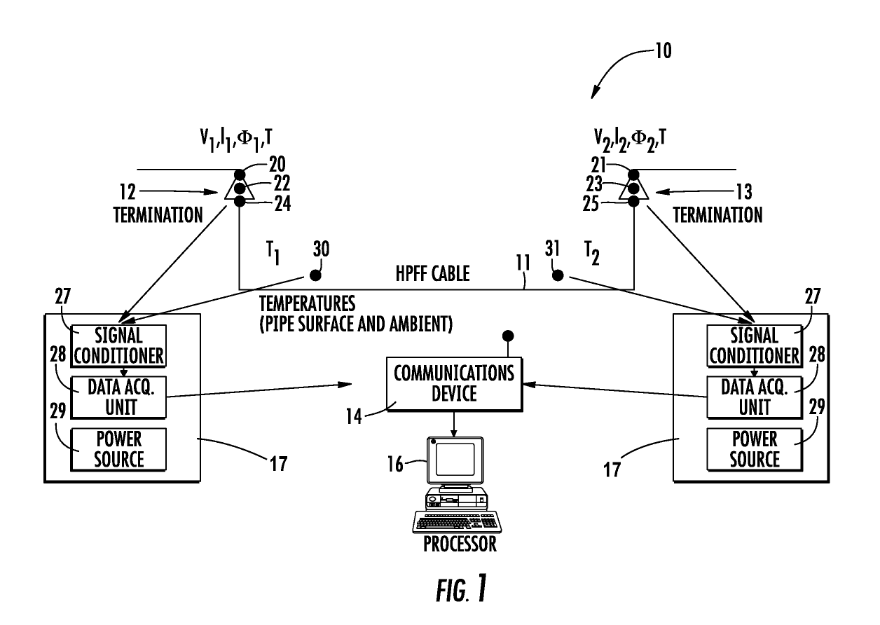

Referring to the drawings, an on-line monitoring system in accordance with an embodiment of the invention is illustrated in FIG. 1 and shown generally at reference numeral 10. The monitoring system 10 includes a cable circuit 11 disposed along a section of underground cable having first and second, spaced-apart terminals 12 and 13. The system 10 further includes a communications device 14 for transmitting data gathered at the terminals 12 and 13 and a central processing unit 16 having software thereon for processing data received from the communications device 14, signaling alarm systems, circuit modeling, and displaying results on a display.

Generally, the invention uses a real time on-line system to monitor dissipation factor of transmission laminar dielectric cable insulation systems by measuring voltage, current, and phase angle from the terminals 12 and 13 of the cable circuit 11, along with synchronized communications, circuit modeling, and real time data processing.

The monitoring system 10 monitors cable insulation losses by measuring quantities from both terminals 12 and 13 of the cable circuit 11, such as, voltages, currents, and phase angles. The invention uses synchronization and communication technologies to measure the quantities at an exact moment from both cable terminals 12 and 13—the measured data from both terminals 12 and 13 of the cable circuit 11 may be compared and dielectric loss calculated in real time. The measured data is then transmitted by the communications device 14 to the central data processing unit 16 to determine the insulation losses. The invention does not require circuit outages and provides continuous monitoring and trending.

Quantities that can readily be obtained from each terminal 12 and 13 of the cable circuit 11 include voltages (V₁ and V₂), currents (I₁ and I₂), and phase angles (φ₁ and φ₂), including waveshape and magnitude information. With present synchronization and communication technologies and accurate satellite clocks, measurements may be made from both terminals 12, 13 of the circuit 11 at one time (T) using a synchronization device 17 and transmitted by the communications device 14 to the central processing unit 16. Temperatures (T₁ and T₂), for example, on high-pressure fluid-filled (HPFF) cable pipe or self-contained fluid-filled cable surface, may also be measured along the circuit 11.

In order to collect the required data, the following components are disposed at each terminal 12, 13 of the cable circuit 11:
Voltage transducers 20, 21 (power frequency, all phases);
Current transducers 22, 23 (power frequency, all phases); and
Phase angle transducers 24, 25 (power frequency, all phases).
   In addition, a signal conditioning device 27, a data acquisition unit 28, and a power source 29 are disposed at each terminal. The power source 29 provides power to all necessary components, the signal conditioning device 27 conditions the signals generated by the transducers 20-25, and the data acquisition unit 28 acquires all conditioned data for transmission by the communications device 14. Also, at locations near and far from pipe or cable surfaces, temperature sensors 30 and 31 for pipe or cable surfaces, ambient air and soil are used.

The data processing unit 16 calculates quantities from the measured data and system modeling to derive a value of insulation losses for the cable circuit loaded and energized by the system voltage. The calculated quantities include power losses going into the cable circuit 11; power losses going into the load supplied by the cable circuit 11; conductor losses; steel pipe losses; skid wire losses; sheath losses; losses through grounding loops; insulation temperature; losses caused by temperature variation; insulation losses; dissipation factor (tan δ) or insulation losses; and trending and alarms.

The system 10 is designed for high-pressure fluid-filled and self-contained fluid-filled cable systems from 138 kV to 345 kV. It can be expanded to other medium voltage or extruded dielectric cable systems. The transducers for voltage 20 and 21, current 22 and 23, phase angle 24 and 25, and temperature 30 and 31 measurements are installed in an outdoor environment. Installation and operation of the monitoring system components do not affect operation of the cable circuit 11. The monitoring system 10 provides protection from high voltage, initial charging current, transient overvoltage and environmental impacts. The system 10 applies correction factors for all non-insulation losses in the measuring systems.

The foregoing has described a monitoring system and method for continually assessing the condition of underground power cables. While specific embodiments of the present invention have been described, it will be apparent to those skilled in the art that various modifications thereto can be made without departing from the spirit and scope of the invention. Accordingly, the foregoing description of the preferred embodiment of the invention and the best mode for practicing the invention are provided for the purpose of illustration only and not for the purpose of limitation.

We claim:

1. A monitoring system adapted to assess insulation losses of an underground power cable, comprising:
(a) a cable circuit having first and second, spaced-apart terminals, the cable circuit being disposed along a section of the underground power cable;
(b) a communications device adapted to transmit data gathered at the first and second terminals; and
(c) a processor adapted to receive and process the data from the communications device.

2. The monitoring system according to claim 1, further including at least one voltage transducer positioned at each of the first and second terminals, the at least one voltage transducer being adapted to collect voltage data at each of the first and second terminals.

3. The monitoring system according to claim 1, further including at least one current transducer positioned at each of the first and second terminals, the at least one current transducer being adapted to collect current data at each of the first and second terminals.

4. The monitoring system according to claim 1, further including at least one phase angle transducer positioned at each of the first and second terminals, the at least one phase angle transducer being adapted to collect phase angle data at each of the first and second terminals.

5. The monitoring system according to claim 1, further including at least one temperature sensor adapted to collect temperature data.

6. The monitoring system according to claim 1, further including a power source disposed at each of the first and second terminals to provide power to components located at each of the first and second terminals.

7. The monitoring system according to claim 1, further including at least one signal conditioner adapted to condition data signals generated by transducers located at each of the first and second terminals prior to the data being acquired.

8. The monitoring system according to claim 7, further including at least one data acquisition unit adapted to acquire the conditioned data signals from the signal conditioner and provide the conditioned data signals to the communications device for transmission to the processor.

9. A method of determining insulation losses of an underground power cable, comprising the steps of:
(a) providing a cable circuit having first and second, spaced-apart terminals;
(b) acquiring data signals collected at the first and second terminals;
(c) transmitting the data signals to a processor;
(d) using the processor to process the data signals; and
(e) displaying results of the processed data signals.

10. The method according to claim 9, further including the step of collecting data at the first and second terminals.

11. The method according to claim 10, wherein the step of collecting data is performed using transducers positioned at each of the first and second terminals.

12. The method according to claim 11, wherein the transducers are selected from the group consisting of voltage transducers, current transducers, and phase angle transducers.

13. The method according to claim 9, further including the step of providing a data acquisition unit to acquire the data.

14. The method according to claim 9, further including the step of providing a signal conditioner to condition the data signals.

15. The method according to claim 9, further including the step of providing a synchronization device to measure the data at the same time and a communications device to transmit the data signals to the processor.
